(19) United States
(12) Patent Application Publication
(10) Pub. No.: US 2025/0155489 A1
(43) Pub. Date: May 15, 2025

(54) METHOD FOR EVALUATING SEMICONDUCTOR DEVICE, METHOD FOR PRODUCING SEMICONDUCTOR DEVICE, AND SEMICONDUCTOR DEVICE

(71) Applicant: Mitsubishi Electric Corporation, Tokyo (JP)

(72) Inventor: Akio MATSUSHITA, Tokyo (JP)

(73) Assignee: Mitsubishi Electric Corporation, Tokyo (JP)

(21) Appl. No.: 18/839,929

(22) PCT Filed: Jun. 30, 2022
(86) PCT No.: PCT/JP2022/026337

§ 371 Date: Aug. 20, 2024

(51) Int. Cl. G01R 31/26; H01L 23/29; H01L 23/66

(52) U.S. Cl. CPC G01R 31/2601; H01L 23/293; H01L 23/66

(57) ABSTRACT

In a method for evaluating a semiconductor device wherein a transmission line (2) is provided on a substrate (1), and a semiconductor chip (5) and a surface mount device (7a˜7d) are mounted on the substrate (1) and connected to each other by the transmission line (2). First, a resin cover (9) including a first recess (10) provided in a portion corresponding to the semiconductor chip (5) and a second recess (11) provided in a portion corresponding to the surface mount device (7a˜7d) is prepared. Next, the resin cover (9) is aligned such that the first recess (10) accommodates the semiconductor chip (5) and the second recess (11) accommodates the surface mount device (7a˜7d), and the resin cover (9) is pressed against the transmission line (2) by means of a hold-down jig (12) to evaluate the semiconductor device. The resin cover (9) has a relative dielectric constant of 3 to 4.

### FIELD

The present disclosure relates to a method for evaluating a semiconductor device, a method for producing a semiconductor device, and a semiconductor device.

### BACKGROUND

In a microwave integrated circuit module for mobile phone terminals or mobile base stations, in particular, in a power amplifier module, a compound semiconductor chip, typically GaAs or GaN, and a plurality of surface mount devices (SMDs) are mounted on a multi-layer substrate, and the upper surface is sealed by a molding resin (see, for example, Non Patent Literature 1). In particular, in a microwave integrated module having an operating frequency of several GHz or lower, the surface mount devices are actively used, instead of integrating all of inductance or capacitance elements on the semiconductor chip. The surface mount devices are more effective in reducing a circuit loss and can reduce cost by controlling an increase in a chip area. With the use of surface mount devices for a part of the circuit constant, the RF characteristics can be finely adjusted.

In the power amplifier module in which the semiconductor chip and the surface mount devices are mounted on the multi-layer substrate for L/S/C bands (about 1 to 6 GHZ), a disparity between design and actual measurement occurs due to various factors, such as variations in thickness of dielectric layers or line width, the wire shape or length, or differences in the design model of the semiconductor chip on the substrate. For this reason, fine adjustment of the RF characteristics is required.

Thus, typically, for improving the initial RF characteristics, the circuit constant is adjusted such that the constants of the surface mount devices used in designing are changed so as to approximate the actual measurement to roughly around the design values. This adjustment is carried out prior to mold sealing, but there is a problem in that the RF characteristics change before and after the mold sealing. This change occurs because the transmission lines, the surface mount devices, and the like on the surface of the substrate are covered by a molding material, which causes the effective dielectric constant and the equivalent dielectric loss tangent of their periphery to change.

In an RF circuit that operates at the GHz band, such as the power amplifier module for base stations, including the 5th generation mobile communication system (5G), the RF characteristics are likely to differ before and after the mold sealing. The relative dielectric constant of a molding resin is higher than that of the air and the molding resin has a dielectric loss tangent. This leads to an RF loss. The Doherty amplifier requires a delay line for forming a phase difference between a carrier amplifier and a peak amplifier. When this delay line is formed by a distributed constant circuit such as a transmission line on the surface layer of the substrate, the effective dielectric constant or the like of the delay line changes by being affected by the resin molding material. The change affects the phase difference between the carrier amplifier and the peak amplifier of the Doherty amplifier, significantly contributing to the fluctuation of the characteristics. Therefore, in the Doherty amplifier, it is difficult to predict the RF characteristics after mold sealing as compared to the conventional amplifier.

### CITATION LIST

### Non Patent Literature

[Non Patent Literature 1] IEEE TRANSACTIONS ON MICROWAVE THEORY AND TECHNIQUES, VOL. 64, NO. 10, October 2016, pp. 3244-3254

### SUMMARY

### Technical Problem

After mold sealing, it is difficult to transfer the surface mount devices. Therefore, conventionally, changes in the RF characteristics before and after the mold sealing have been roughly identified so as to adjust the RF characteristics of a module without molding. That is, a workflow was repeated in which the surface mount devices are transferred, mold resin sealing is performed, the fluctuation amount is confirmed, and if there is any problem, another sample is used to restart from the adjustment of the surface mount devices. This repeated flow has been an obstacle to work time reduction.

The present disclosure has been made to solve the problem as described above, and the object of the present disclosure is to obtain a method for evaluating a semiconductor device that can significantly reduce work time, a method for producing the semiconductor device, and the semiconductor device.

### Solution to Problem

A method according to the present disclosure for evaluating a semiconductor device wherein a transmission line is provided on a surface of a substrate, and a semiconductor chip and a surface mount device are mounted on the surface of the substrate and connected to each other by the transmission line, includes: preparing a resin cover including a first recess provided in a portion corresponding to the semiconductor chip and a second recess provided in a portion corresponding to the surface mount device; and aligning the resin cover such that the first recess accommodates the semiconductor chip and the second recess accommodates the surface mount device, and pressing the resin cover against the transmission line by means of a hold-down jig so as to evaluate the semiconductor device, wherein the resin cover has a relative dielectric constant of 3 to 4.

A method according to the present disclosure for producing a semiconductor device includes: forming a transmission line on a surface of a substrate; mounting a semiconductor chip and a surface mount device on the surface of the substrate and connecting the semiconductor chip and the surface mount device to each other by the transmission line; preparing a resin cover including a first recess provided in a portion corresponding to the semiconductor chip and a second recess provided in a portion corresponding to the surface mount device; and aligning the resin cover such that the first recess accommodates the semiconductor chip and the second recess accommodates the surface mount device, and pressing the resin cover against the transmission line by means of a hold-down jig so as to evaluate the semiconductor device, wherein the resin cover has a relative dielectric constant of 3 to 4.

A semiconductor device according to the present disclosure includes: a substrate; a transmission line provided on a surface of the substrate; a semiconductor chip and a surface mount device mounted on the surface of the substrate and connected to each other by the transmission line; a solder resist covering the transmission line; and a molding resin covering the transmission line, the semiconductor chip, the surface mount device and the solder resist, wherein the solder resist includes a resist having a relative dielectric constant of 4.5 or greater.

### Advantageous Effects of Invention

In the method according to the present disclosure for evaluating a semiconductor device and the method according to the present disclosure for producing a semiconductor device, the transmission line, the characteristics of which significantly vary depending on whether the molding resin is present, is covered by the resin cover, so that the equivalent dielectric constant of the transmission line is equalized with the characteristics after the full molding. Accordingly, the RF characteristics after the mold sealing can be acquired through measurement before the mold sealing. Since the mold sealing is not yet performed, the characteristics can be adjusted by transferring the surface mount device. As a result, work time for adjusting the RF characteristics can be significantly reduced.

In the semiconductor device according to the present disclosure, the solder resist having a higher relative dielectric constant is provided on the transmission line. In substances having a higher relative dielectric constant, the wavelength is reduced, causing the concentration of the electric field energy. Therefore, with the solder resist provided, the impact on the equivalent dielectric constant of the air or the molding resin on the solder resist is reduced. Accordingly, as compared to a case without the solder resist, the change in the RF characteristics before and after the molding can be suppressed. As a result, the work time for adjusting the RF characteristics can be significantly reduced.

### BRIEF DESCRIPTION OF THE DRAWINGS

FIG. 1 is a top view showing a semiconductor device before mold sealing according to an embodiment 1.

FIG. 2 is a cross-sectional view taken along I-II of FIG. 1.

FIG. 3 is a cross-sectional view showing a method for producing the semiconductor device according to the embodiment 1.

FIG. 4 is a cross-sectional view showing a method for producing the semiconductor device according to the embodiment 1.

FIG. 5 is a chart showing the characteristics of the power amplifier before and after the mold sealing.

FIG. 6 is a cross-sectional view showing a modification of the semiconductor device according to the embodiment 1.

FIG. 7 is a top view showing the semiconductor device before the mold sealing according to an embodiment 2.

FIG. 8 is a cross-sectional view taken along I-II of FIG. 7.

FIG. 9 is a cross-sectional view showing the semiconductor device after the mold sealing according to the embodiment 2.

### DESCRIPTION OF EMBODIMENTS

A method for evaluating a semiconductor device, a method for producing a semiconductor device, and a semiconductor device according to the embodiments of the present disclosure will be described with reference to the drawings. The same components will be denoted by the same symbols, and the repeated description thereof may be omitted.

### Embodiment 1

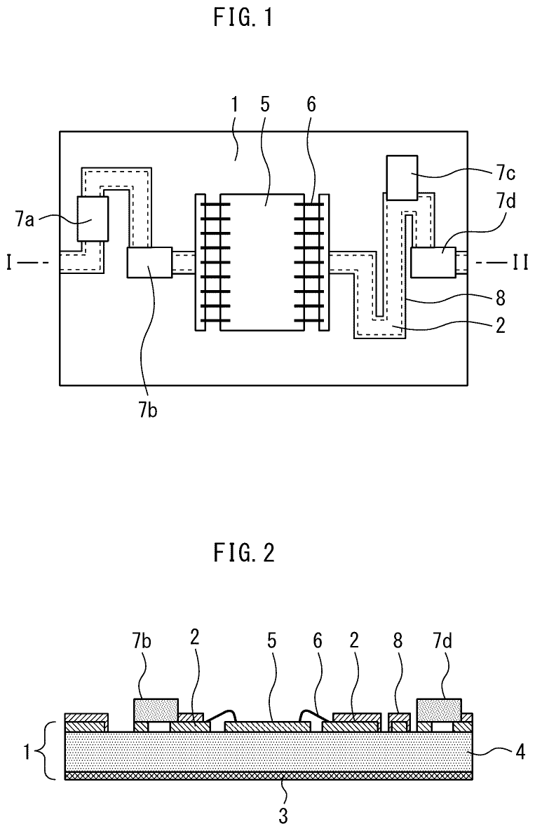

FIG. 1 is a top view showing a semiconductor device before mold sealing according to an embodiment 1. FIG. 2 is a cross-sectional view taken along I-II of FIG. 1. The semiconductor device is a microwave power amplifier module that operates at a GHz band.

A transmission line 2 is provided on a surface of a multi-layer substrate 1 having a thickness of about 400 μm. The transmission line 2 is made of copper. On a back surface of the multi-layer substrate 1, a back surface metal 3 for GND connection is provided. The transmission line (not shown) is provided also in each inner layer of the multi-layer substrate 1. Dielectric layers 4 are provided between the layers of the multi-layer substrate 1. The material of the dielectric layers 4 is an epoxy resin, but may be, for example, a fluorocarbon resin, a ceramic material such as alumina, or other materials. The transmission line 2 on the surface side, the transmission lines in the inner layers, and the back surface metal 3 are connected with each other via a through-hole (not shown) that extends through the dielectric layers 4, as necessary.

A semiconductor chip 5 is mounted on the surface of the multi-layer substrate 1. A wire 6 connects each of an input and an output of the semiconductor chip 5 to the transmission line 2. Surface mount devices 7a, 7b are connected in series to the transmission line 2 on the input side of the semiconductor chip 5. The surface mount devices 7a, 7b are an inductor, a capacitor, a resistor, and the like that constitute an input impedance matching circuit. A surface mount device 7c is connected in parallel to the transmission line 2 on the output side of the semiconductor chip 5, and a surface mount device 7d is connected in series to the transmission line 2 on the output side. One electrode of the surface mount device 7c is connected to the transmission line 2, and the other electrode is connected to the back surface metal 3 via a through-hole (not shown). The surface mount devices 7c, 7d are an inductor, a capacitor, a resistor, and the like that constitute an output impedance matching circuit. For simple illustration, four surface mount devices 7a to 7d are shown, but typically, several dozens of surface mount devices are provided.

A solder resist 8 having a thickness of around several dozen μm is stacked on the transmission line 2 for protection of a circuit pattern. The material of the solder resist 8 is an epoxy resin or the like. For the regions where the surface mount devices 7a to 7d are mounted and the regions where the wire 6 is bonded, the solder resist 8 is not formed on the transmission line 2, and metal plating is performed for prevention of copper oxidation.

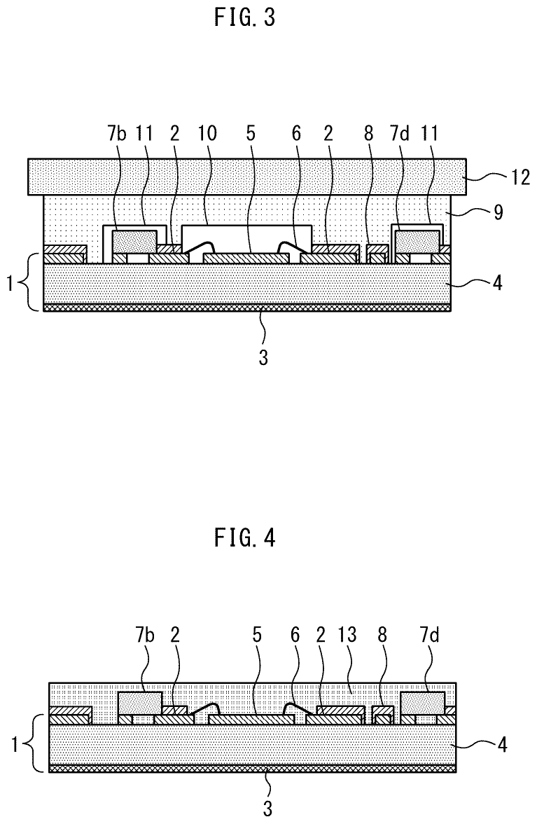

FIG. 3 and FIG. 4 are cross-sectional views showing a method for producing the semiconductor device according to the embodiment 1. A resin cover 9 includes, on its lower surface side, a first recess 10 that is provided in a portion corresponding to the semiconductor chip 5 and the wire 6 and a second recess 11 that is provided in a portion corresponding to the surface mount devices 7a to 7d. The resin cover 9 provided with such first recess 10 and second recess 11 can be accurately formed using NC processing, a 3D printing technique, or the like. The relative dielectric constant of the resin cover 9 is 3 to 4.

The resin cover 9 is aligned with the multi-layer substrate 1 such that the first recess 10 accommodates the semiconductor chip 5 and the wire 6 and the second recess 11 accommodates the surface mount devices 7a to 7d, and the resin cover 9 is overlaid on the semiconductor device. The first recess 10 and the second recess 11 cannot be identified from the outside. The semiconductor chip 5, the surface mount devices 7a to 7d, and the like that are accommodated in the first recess 10 and the second recess 11 are in a hollow state. Note that the surface side of the multi-layer substrate 1 is not entirely hollow, and the multi-layer substrate 1 and the resin cover 9 are partially contacted.

The opening dimension of the first recess 10 is made larger by around 0.2 mm on one side as compared to the regions where the semiconductor chip 5 and the wire 6 are formed, for the purpose of preventing the resin cover 9 from contacting the wire 6. When the surface mount devices 7a to 7d are in a size of 0.6 mm in length×0.3 mm in width, which is referred to as 0603, the mounting error of the surface mount devices 7a to 7d is around +0.15 mm. The opening dimension of the second recess 11 is set to be around 1.0 mm×0.7 mm with an additional margin of 0.05 mm to deal with the mounting error. When the dimensions of the surface mount devices 7a to 7d change, the opening dimension of the second recess 11 also changes. Typically, since several dozens of surface mount devices 7a to 7d are arranged on the multi-layer substrate 1, a plurality of second recesses 11 are provided in the resin cover 9.

Next, current is made to flow through the transmission line 2, the semiconductor chip 5, and the surface mount devices 7a to 7d, while pressing the resin cover 9 against the transmission line 2 by means of a hold-down jig 12, so as to evaluate the RF characteristics of the semiconductor device. The resin cover 9 is detachable and can be easily detached when released from the pressure of the hold-down jig 12. Therefore, it is possible to replace the surface mount devices 7a to 7d or adjust the length or the height of the wire 6 or the like for improving the characteristics, after the characteristics evaluation.

Lastly, the resin cover 9 is detached, and the transmission line 2, the semiconductor chip 5, and the surface mount devices 7a to 7d are sealed by a molding resin 13 as shown in FIG. 4. Since the material of the molding resin 13 is an epoxy resin having a relative dielectric constant of 3 to 4, the resin cover 9 has a relative dielectric constant equivalent to that of the molding resin 13. For example, as a material of the resin cover 9, the same epoxy resin as that of the molding resin 13 is used.

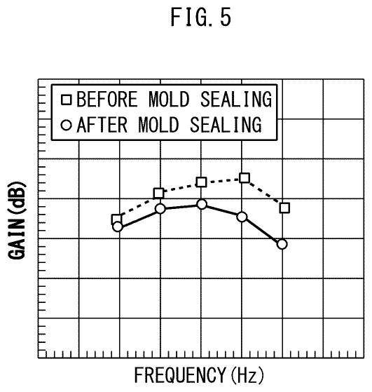

Subsequently, the advantageous effects of the present embodiment will be described. FIG. 5 is a chart showing the characteristics of the power amplifier before and after the mold sealing. It is recognized that differences in the RF characteristics occur before and after the mold sealing. Thus, in the present embodiment, the RF characteristics of the semiconductor device are examined, with a state in which the resin cover 9 is pressed against the transmission line 2 by means of the hold-down jig 12. The resin cover 9 has a relative dielectric constant of 3 to 4, which is equivalent to that of the molding resin 13. The transmission line 2, the characteristics of which significantly vary depending on whether the molding resin 13 is present, is covered by the resin cover 9, so that the equivalent dielectric constant of the transmission line 2 is equalized with the characteristics after the full molding. Accordingly, the RF characteristics after the mold sealing can be acquired through measurement before the mold sealing. Since the mold sealing is not yet performed, the characteristics can be adjusted by transferring the surface mount devices 7a to 7d. As a result, work time for adjusting the RF characteristics can be significantly reduced. Further, since a prototype having the RF characteristics equivalent to those of a prototype subjected to full molding can be produced in a laboratory, the work time at an assembly plant for performing the full molding process can be reduced.

Further, the resin cover 9 is aligned with the multi-layer substrate 1 such that the first recess 10 accommodates the semiconductor chip 5 and the wire 6 and the second recess 11 accommodates the surface mount devices 7a to 7d. In this manner, by using the surface mount devices 7a to 7d as well as the semiconductor chip 5 as an alignment guide, the resin cover 9 can be overlaid on the multi-layer substrate 1 with a high aligning accuracy, and thus, the transmission line 2 can be precisely covered by the resin cover 9.

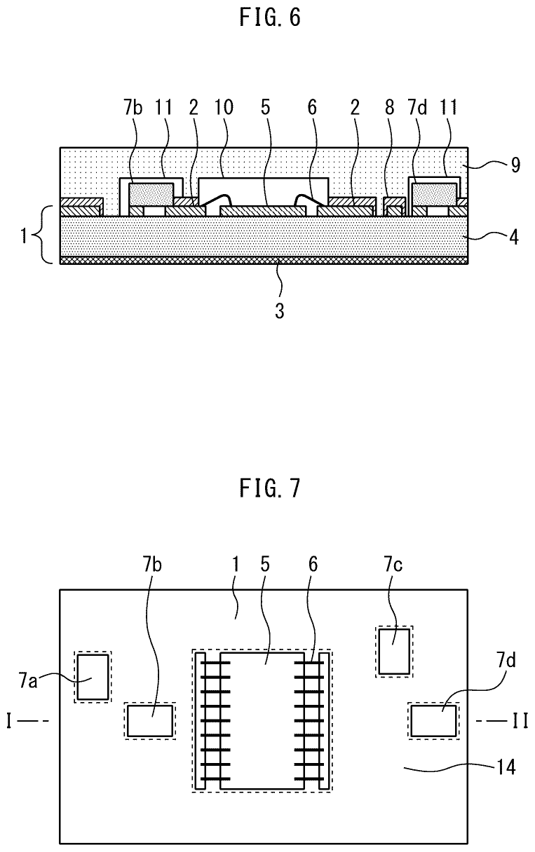

FIG. 6 is a cross-sectional view showing a modification of the semiconductor device according to the embodiment 1. The module in which the resin cover 9 is pressed against the transmission line 2 has the RF characteristics equivalent to those of the typical module after resin sealing. Therefore, the resin cover 9 may be adhesively bonded to the multi-layer substrate 1 using an adhesive or the like (not shown) without performing the mold sealing after removing the resin cover 9. In this manner, a prototype already sealed can be easily produced at a laboratory. As a result, when after adjustment, full molding work at an assembly plant for performing the full molding process again is expected, the process time can also be reduced.

Note that if the resin cover 9 is soft, when the resin cover 9 is pressed against the transmission line 2, the resin cover 9 is distorted in shape and contacts the wire 6 or the like on the surface layer of the multi-layer substrate 1, which could affect the characteristics of the module. Therefore, the resin cover 9 is preferably hard.

### Embodiment 2

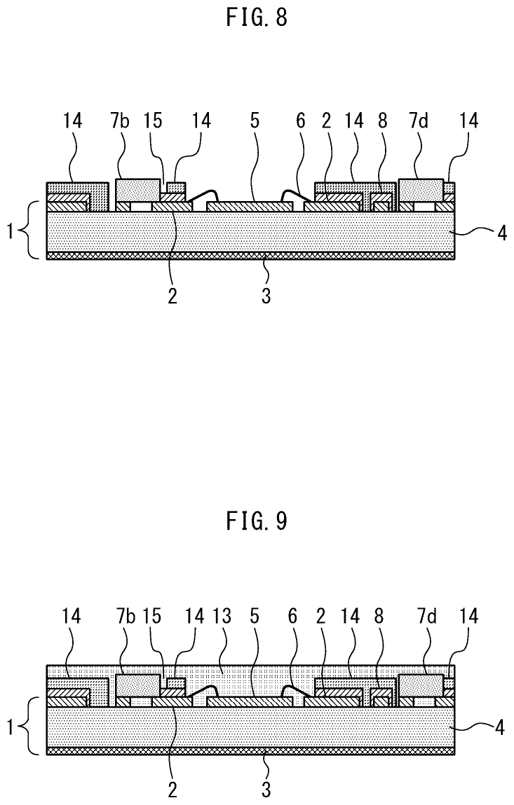

FIG. 7 is a top view showing the semiconductor device before the mold sealing according to an embodiment 2. FIG. 8 is a cross-sectional view taken along I-II of FIG. 7. In the present embodiment, a solder resist 14 having a relative dielectric constant of 4.5 or greater is stacked on the surface side of the multi-layer substrate 1, excluding the areas of around several hundred μm in the surroundings of the semiconductor chip 5, the wire 6, and the surface mount devices 7a to 7d. Accordingly, a two-layer structure of the solder resist 8 having a relative dielectric constant of 3 to 4 and the solder resist 14 having a relative dielectric constant of 4.5 or greater is provided on the transmission line 2. The other configurations are the same as those of the embodiment 1.

Further, for enabling the surface mount devices 7a to 7d to be transferred, a gap 15 is formed between the solder resist 14 and the surface mount devices 7a to 7d, the gap 15 having around several hundred μm to the extent that allows tweezers to be inserted between the solder resist 14 and the surface mount devices 7a to 7d. When the solder resist 14 is at around the same height as that of the surface mount devices 7a to 7d, it is difficult to pick and transfer the surface mount devices 7a to 7d, using tweezers. For this reason, it is preferable that the height of the solder resist 14 is lower than the height of the surface mount devices 7a to 7d, and is around half of the height of the surface mount devices 7a to 7d. For example, since the height of the surface mount device referred to as 0603 is 0.3 mm, the height of the solder resist 14 is around 0.15 mm.

FIG. 9 is a cross-sectional view showing the semiconductor device after the mold sealing according to the embodiment 2. The RF characteristics of the semiconductor device are evaluated and the surface mount devices 7a to 7d are transferred to adjust the characteristics, and thereafter, the surface is sealed by the molding resin 13 while maintaining the solder resist 14.

Before and after the molding, the air having a relative dielectric constant of 1 present on the solder resist on the transmission line 2 is replaced with the molding resin 13 having a relative dielectric constant of 3 to 4. As a result, the equivalent dielectric constant of the transmission line 2 as a whole fluctuates, leading to the fluctuation of the RF characteristics. Thus, in the present embodiment, the solder resist 14 having a higher relative dielectric constant is provided on the transmission line 2. In substances having a higher relative dielectric constant, the wavelength is reduced, causing the concentration of the electric field energy. Therefore, with the solder resist 14 provided, the impact on the equivalent dielectric constant of the air or the molding resin 13 on the solder resist 14 is reduced. Accordingly, as compared to a case without the solder resist 14, the change in the RF characteristics before and after the molding can be suppressed. As a result, a sample having the RF characteristics that are very close to those of a mold sealed product at the time of mass-production can be produced for a short period of time. Since the mold sealing is not yet performed, the surface mount devices 7a to 7d can be transferred to adjust the characteristics. As a result, the work time for adjusting the RF characteristics can be significantly reduced.

Further, since the strength of the electric field is attenuated toward the upper side away from the transmission line 2, it is possible to suppress the fluctuation of the equivalent dielectric constant as a portion where the dielectric constant changes is distanced farther from the transmission line 2. Thus, the solder resist 14 is formed thicker than the typical solder resist 8 having a thickness of around several dozen μm, and is provided up to half in height of the surface mount devices 7a to 7d.

Note that since portions other than the transmission line 2 also change to some extent depending on whether the molding resin 13 is coated, the characteristics tend to be constantly stabilized by providing the solder resist 14. However, as compared to the portion of the transmission line 2, the fluctuation is minor and the quantitative effectiveness cannot be expected so much. Therefore, the solder resist 14 on the portions other than those on the transmission line 2 is not essential.

Moreover, even without the solder resist 8 having a relative dielectric constant of 3 to 4, as long as the solder resist 14 having a relative dielectric constant of 4.5 or greater is stacked with a thickness of around half in height of the surface mount devices 7a to 7d, the advantageous effects can be obtained.

### REFERENCE SIGNS LIST

1 multi-layer substrate; 2 transmission line; 5 semiconductor chip; 7a˜7d surface mount device; 8,14 solder resist; 9 resin cover; 10 first recess; 11 second recess; 12 hold-down jig; 13 molding resin; 15 gap

1. A method for evaluating a semiconductor device wherein a transmission line is provided on a surface of a substrate, and a semiconductor chip and a surface mount device are mounted on the surface of the substrate and connected to each other by the transmission line, comprising:
preparing a resin cover including a first recess provided in a portion corresponding to the semiconductor chip and a second recess provided in a portion corresponding to the surface mount device; and
aligning the resin cover such that the first recess accommodates the semiconductor chip and the second recess accommodates the surface mount device, and pressing the resin cover against the transmission line by means of a hold-down jig so as to evaluate the semiconductor device,
wherein the resin cover has a relative dielectric constant of 3 to 4.

2. A method for producing a semiconductor device comprising:
forming a transmission line on a surface of a substrate;
mounting a semiconductor chip and a surface mount device on the surface of the substrate and connecting the semiconductor chip and the surface mount device to each other by the transmission line;
preparing a resin cover including a first recess provided in a portion corresponding to the semiconductor chip and a second recess provided in a portion corresponding to the surface mount device; and
aligning the resin cover such that the first recess accommodates the semiconductor chip and the second recess accommodates the surface mount device, and pressing the resin cover against the transmission line by means of a hold-down jig so as to evaluate the semiconductor device,
wherein the resin cover has a relative dielectric constant of 3 to 4.

3. The method for producing a semiconductor device according to claim 2, further comprising, after evaluating, sealing the transmission line, the semiconductor chip, and the surface mount device by a molding resin having a relative dielectric constant of 3 to 4.

4. The method for producing a semiconductor device according to claim 2, further comprising, after evaluating, adhesively bonding the resin cover to the substrate.

5. A semiconductor device comprising:
a substrate;
a transmission line provided on a surface of the substrate;
a semiconductor chip and a surface mount device mounted on the surface of the substrate and connected to each other by the transmission line;
a solder resist covering the transmission line; and
a molding resin covering the transmission line, the semiconductor chip, the surface mount device and the solder resist,
wherein the solder resist includes a resist having a relative dielectric constant of 4.5 or greater, and
the solder resist includes a two-layer structure of a resist having a relative dielectric constant of 3 to 4 and a resist having a relative dielectric constant of 4.5 or greater.

6. (canceled)

7. The semiconductor device according to claim 5, wherein the solder resist is provided up to half in height of the surface mount device.

8. The semiconductor device according to claim 5, wherein a gap is formed between the solder resist and the surface mount device.

9. The semiconductor device according to claim 5, wherein a height of the solder resist is lower than a height of the surface mount device.
